(19) United States
(12) Patent Application Publication
(10) Pub. No.: US 2011/0013655 A1
(43) Pub. Date: Jan. 20, 2011

(54) SEMICONDUCTOR LASER DEVICE

(75) Inventors: Tadashi Takase, Tokyo (JP); Hitoshi Tada, Tokyo (JP); Hiroaki Maehara, Tokyo (JP); Yoshihiro Hisa, Tokyo (JP); Hitoshi Sakuma, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: MITSUBISHI ELECTRIC CORPORATION, Tokyo (JP)

(21) Appl. No.: 12/823,179

(22) Filed: Jun. 25, 2010

(30) Foreign Application Priority Data
Jul. 17, 2009 (JP) 2009-168602

(51) Int. Cl. H01S 5/22

(52) U.S. Cl. 372/45.01

(57) ABSTRACT

In a semiconductor laser device a dual wavelength semiconductor laser chip is joined onto a submount, junction down, to reduce built-in stress produced between the laser chip and the submount and to decrease polarization angles of the two respective lasers. SnAg solder is used to join the dual wavelength semiconductor laser chip onto the submount. When joining, with respect to each of the two lasers, a ratio of a distance between the center line of a waveguide and an end, placed at a lateral side of the laser chip, of a portion joining the laser chip and the submount, to a distance between the center line of the waveguide and another end, placed toward the center of the laser chip, of the portion joining the laser chip and the submount, falls within a range of 0.69 to 1.46.

### BACKGROUND OF THE INVENTION

1. Field of the Invention

The present invention relates to a semiconductor laser device, especially a monolithic-dual-wavelength semi-conductor laser device having a ridge-waveguide structure.

2. Description of the Prior Art

Because of development in digital information technology, optical recording media such as DVD-R and CD-R are frequently used. In recent years, a writable optical disc drive compatible with DVD-R, CD-R, and the like is normally installed in a notebook PC as well as a desktop PC. Thus, it is demanded that the optical pick-up—a main component of the writable optical disc drive—be miniaturized, reduced in weight, and reduced in cost, so that efforts are being made to reduce the number of optical components and simplify its manufacturing process. Conventionally, as light source for an optical pick-up compatible with both DVD and CD optical recording methods, two individual semiconductor laser devices, a semiconductor laser device for DVD that oscillates 650-nm-wavelength-band light and a semiconductor laser device for CD that oscillates 780 nm-wavelength-band light, have been used. In recent years, a dual-wavelength semiconductor laser device is used which has advantages for reducing the number of optical components and simplifying its manufacturing process. In particular, a monolithic-dual-wavelength semiconductor laser device in which a laser device for 650 nm-wavelength-band laser and a laser device for 780 nm-wavelength-band laser are integrated on a substrate, is readily applicable because of high controllability of the distance between the two light emitting points and the directions of the two laser beams and is also easily manufacturable, and thus, its development is now actively facilitated.

To improve DVD and CD in recording speed, it has been required that semiconductor laser device has high light outputs. Recently, optical pick-ups have a tendency to increase their optical loss, because an optical disc that needs to use therewith a blue semiconductor laser device (405 nm wavelength band) as a light source has appeared on the market. For this reason, 650 nm-wavelength-band lasers and 780 nm-wavelength-band lasers are required to have a higher light output. Furthermore, required is such a semiconductor laser device that can operate even under a high temperature environment and realize a high optical coupling efficiency by an optical pick-up which makes an emitted light efficiently reach an optical disc face. From the view point of the optical coupling efficiency, a monolithic-dual-wavelength semi-conductor laser device is useful because of its excellent controllability for launching directions of two laser beams-650 nm-band and 780 nm-band. An example of such a semiconductor laser is described in Japanese Patent Application Laid-Open Publication No. 2008-258341 (Patent document 2).

In the semiconductor laser device required to have a high light output as described above, it is necessary to enhance its heat dissipation performance on the heat produced from a laser chip. Thus, in the assembling step, the laser chip is joined to a submount typically with junction down. However, when joining by junction down, the thermal expansion coefficient difference between the laser chip and the submount causes built-in stress on an optical waveguide (a light emitting portion), degrading the polarization angle of the laser beam. Especially in the case of a laser device with ridge-waveguide or a laser device with buried ridge-waveguide, a convex shape of its ridge structure makes its built-in stress concentrated at the ridge structure, thereby easily degrading the polarization angle. In the case of a laser chip used for a dual wavelength semiconductor laser device, two optical waveguides cannot be placed at the same time at the center of the chip, so that the respective waveguides are typically placed at positions 55 μm away from the center of the chip, rightward and leftward, respectively.

Thus, left-right asymmetric built-in stresses are applied to the respective waveguides, further degrading their polarization angles. Then, a proposal of optimizing the width and thickness of the submount has been made to improve their polarization angles. This kind of semiconductor laser is described in Japanese Patent Application Laid-Open Publication No. 2009-130206 (Patent document 1).

### SUMMARY OF THE INVENTION

In an optical system of an optical pick-up, a polarizing element is used to improve accuracy of reading data on an optical disc, and the laser beam is coupled with a lens through the polarizing element. Because the larger the polarization angle is, the more reduced the intensity of the laser beam after passing the polarizing element is, it is necessary that the absolute value of the polarization angle is small.

However, when a light emitting semiconductor device is manufactured according to a configuration of Patent document 1 so as to improve the polarization angle, its manufacturing efficiency is degraded due to the optimized submount's width and thickness, bringing a rising cost problem. In addition, when AuSn is used as a solder for the submount, similarly to the case of a submount typically used in a conventional light emitting semiconductor device, its eutectic point is a high temperature of 280° C. and therefore, it is unable to sufficiently reduce built-in stress produced between a laser chip and the submount, resulting in an insufficient improvement in polarization angle.

The present invention is made to solve the problem describe above, and provides a semiconductor laser device that can make the laser beam's polarization angle smaller without raising costs of the submount.

A semiconductor laser device includes a dual wavelength semiconductor laser chip of a ridge-waveguide type, that has a first laser region and a second laser region on a substrate, and has an insulation trench between the first laser region and the second laser region, and a submount to which the dual wavelength semiconductor laser chip is joined by junction down, wherein the dual wavelength semiconductor laser chip is being joined to the submount by means of an SnAg solder.

Furthermore, a semiconductor laser device according to the present invention includes a dual wavelength semiconductor laser chip of a ridge-waveguide type, that has on a substrate a first laser region including a first waveguide and a second laser region including a second waveguide, and has an insulation trench between the first laser region and the second laser region, and a submount to which the dual wavelength semiconductor laser chip is joined by junction down, wherein the dual wavelength semiconductor laser chip is being joined to the submount by means of a solder having a melting temperature of 221° C. or less, and wherein dimensions of the semiconductor laser device follow the conditions expressed below:

0.69≦b/a≦1.46, and 0.69≦b′/a′≦1.46

where

a symbol a is a distance between the center line of the first waveguide and a joining end that is determined by an end of a joined portion of the first laser region and the submount and that is placed toward the insulation trench,

a symbol b is a distance between the center line of the first waveguide and another joining end that is determined by another end of the joined portion of the first laser region and the submount and that is placed toward a lateral side of the substrate located near the first laser region,

a symbol a′ is a distance between the center line of the second waveguide and a joining end that is determined by an end of a joined portion of the second laser region and the submount and that is placed toward the insulation trench,

a symbol b′ is a distance between the center line of the second waveguide and another joining end that is determined by another end of the joined portion of the second laser region and the submount and that is placed toward a lateral side of the substrate located near the second laser region.

According to the present invention, a semiconductor laser device emitting laser beams with small polarization angles can be obtained without raising costs of a submount.

### BRIEF DESCRIPTION OF DRAWINGS

FIG. 1 is an outlined cross-sectional view that illustrates the structure of a semiconductor laser device according to an embodiment of the present invention;

FIG. 2 is an outlined cross-sectional view that illustrates the structure of a dual wavelength semiconductor laser chip according to the embodiment of the present invention;

FIG. 3 is an outlined top view that illustrates the structure of the dual wavelength semiconductor laser chip according to the embodiment of the present invention;

FIG. 4 is an outlined graph that shows how the polarization angle of a laser emitted from a semiconductor laser device according to an embodiment of the present invention varies;

FIG. 5 is an outlined graph that shows how the polarization angle of a laser emitted from a semiconductor laser device according to an embodiment of the present invention varies;

FIG. 6 is an outlined graph that shows how the polarization angle of a laser emitted from a semiconductor laser device according to an embodiment of the present invention varies;

FIG. 7 is an outlined graph that shows how the polarization angle of a laser emitted from a semiconductor laser device according to an embodiment of the present invention varies;

FIG. 8 is an outlined cross-sectional view that illustrates the structure of a dual wavelength semiconductor laser chip according to another embodiment of the present invention.

### DETAILED DESCRIPTION OF THE INVENTION

### Embodiment 1

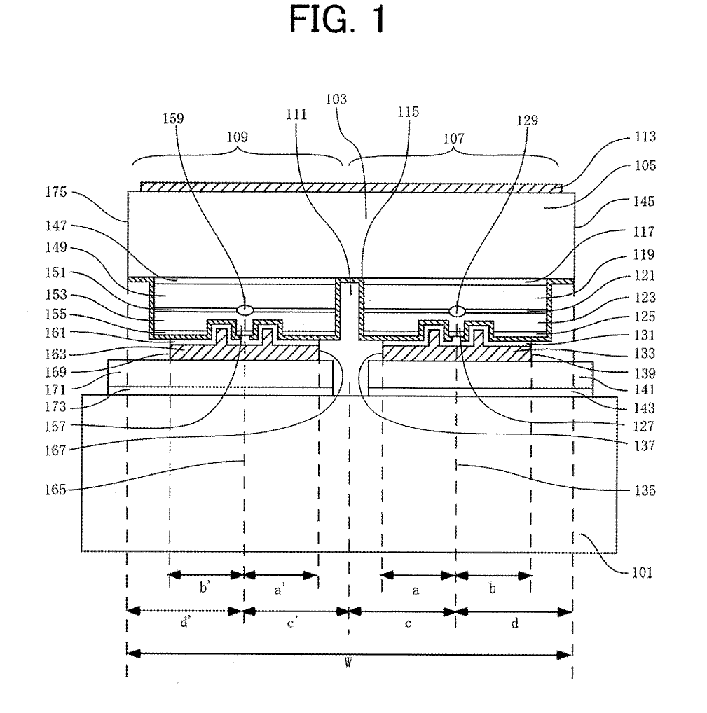

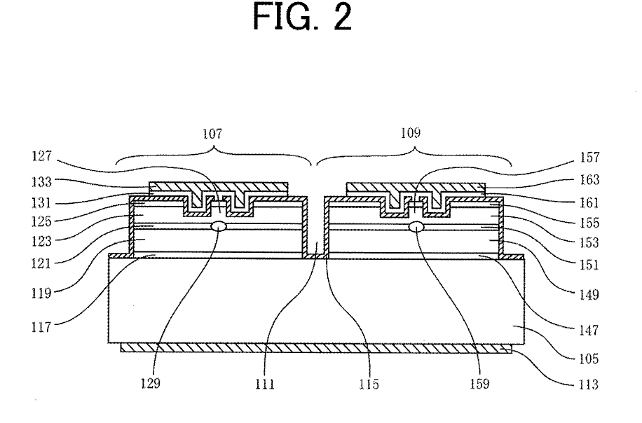

FIG. 1 is a cross-sectional view that illustrates the structure of a semiconductor laser device according to Embodiment 1. FIG. 2 is a cross-sectional view that illustrates the structure of a dual wavelength semiconductor laser chip used in the semiconductor laser device according to Embodiment 1. The semiconductor laser chip 103 is connected onto a submount 101 by junction down. The semiconductor laser chip 103 is a dual wavelength semiconductor laser chip (referred to as a laser chip, below), in which a first semiconductor laser region 107 having a ridge-waveguide for oscillating a 780 nm-wavelength-band laser beam and a second semiconductor laser region 109 having a ridge-waveguide for oscillating a 650 nm-wavelength-band laser beam are monolithically formed on a single n-GaAs substrate 105. In a laser chip 103, in order to electrically insulate the first semiconductor laser region 107 and the second semiconductor laser region 109 from each other, an insulation trench 111 is formed therebetween so that the trench's depth reaches the n-GaAs substrate 105.

The first semiconductor laser region 107 includes a first n-GaAs buffer layer 117, a first n-AlGaInP lower cladding layer 119, a first active layer 121, a first p-AlGaInP upper cladding layer 123, and a first p-GaAs contact layer 125, which are sequentially formed on the n-GaAs substrate 105. The first p-AlGaInP upper cladding layer 123 and the first p-GaAs contact layer 125 are etched to halfway of the first p-AlGaInP upper cladding layer 123 to thereby form a first ridge region 127. The first active layer 121 has a quantum well structure composed of a GaAs-well layer (not illustrated in the figures) and an AlGaAs-barrier layer (not illustrated in the figures) and includes AlGaAs guide layers (not illustrated in the figures) that sandwich the structure at its upper and lower sides. In a portion in the first active layer 121, a portion placed just under the first ridge region 127 constitutes a first waveguide 129 that emits 780 nm-wavelength-band light.

The second semiconductor laser region 109 includes a second n-GaAs buffer layer 147, a second n-AlGaInP lower cladding layer 149, a second active layer 151, a second p-AlGaInP upper cladding layer 153, and a second p-GaAs contact layer 155, which are sequentially formed on the n-GaAs substrate 105. The second p-AlGaInP upper cladding layer 153 and the second p-GaAs contact layer 155 are etched to halfway of the second p-AlGaInP upper cladding layer 153 to thereby form a second ridge region 157. The second active layer 151 has a quantum well structure composed of a GaInP-well layer (not illustrated in the figures) and an AlGaInP-barrier layer (not illustrated in the figures) and includes AlGaInP guide layers (not illustrated in the figures) that sandwich the structure at its upper and lower sides. In a portion in the second active layer 151, a portion placed just under the second ridge region 157 constitutes a second waveguide 159 that emits 650 nm-wavelength-band light.

Top surfaces of the thus laminated semiconductor structures on the n-GaAs substrate 105 are covered, except for top surfaces of the first ridge region 127 and the second ridge region 157, with an insulation film 115 that concentrates currents toward the first waveguide 129 and the second waveguide 159. At upper portions of the first semiconductor laser region 107 and the second semiconductor laser region 109, a first p-side electrode 131 and a second p-side electrode 161 are provided, respectively, and the top surfaces of the first ridge region 127 and the second ridge region 157 are ohmically contacted to the first p-side electrode 131 and the second p-side electrode 161, respectively. On the top surfaces of the first p-side electrode 131 and the second p-side electrode 161, formed are a first-p-side-electrode plating 133 and a second-p-side-electrode plating 163 which are made of such as Au. On the bottom surface of the n-GaAs substrate 105, an n-side electrode 113 is provided as ohmically contacted to the n-GaAs substrate 105.

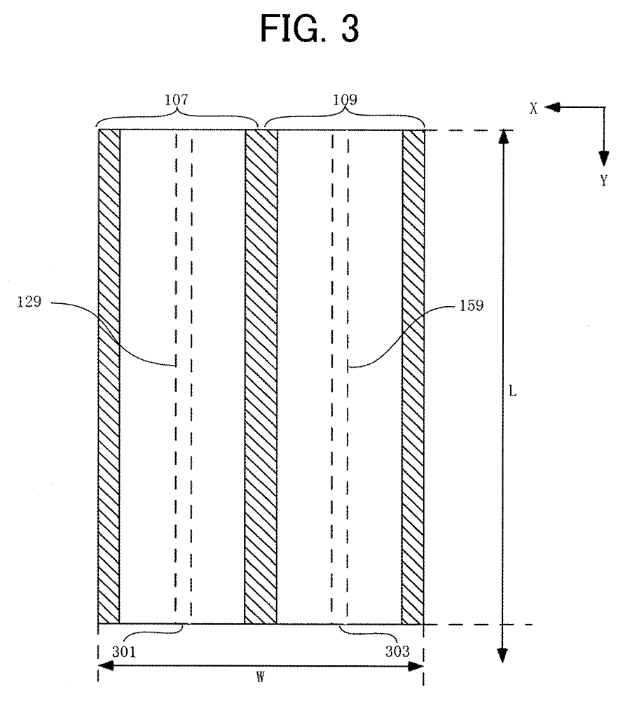

FIG. 3 is a top view of the laser chip 103 in the dual wavelength semiconductor laser device of Embodiment 1. Assuming, as shown in FIG. 3, that the longitudinal direction (an across-the-length-of-resonator direction) of the laser chip 103 is a chip-length direction (the Y direction) and the short length direction (perpendicular to the across-the-length-of-resonator direction) is a chip-width direction (the X direction), the laser chip is formed, for example, in a size of the chip-length-direction length L=2000 μm and the chip-width-direction width W=200 through 240 μm. In addition, because of a necessity to meet the design of typical optical pick-ups, the first waveguide 129 and the second waveguide 159 are formed spaced 110 μm away from each other. In the first waveguide 129 and the second waveguide 159, laser beams are amplified along the chip-length direction so as to be launched from laser exit end faces 301 and 303 having their normal lines in the chip-length direction (Y direction).

As shown in FIG. 1, the laser chip 103 is mounted in a junction down fashion such that the first semiconductor laser region 107 and the second semiconductor laser region 109 come in under the n-GaAs substrate 105, so that the p-side-electrode platings 133 and 163 of the laser chip are joined to SnAg solder layers 141 and 171, respectively, that are formed on electrode layers 143 and 173 on the submount 101 which is, for example, made of AlN and 750 μm wide and 240 μm thick. The bottom surface of the submount 101 is bonded to a can package or a frame package (not illustrated in figures) to complete the dual wavelength semiconductor laser device.

In Embodiment 1, as shown in FIG. 1, with respect to the side of the first semiconductor laser region 107, defined is a distance a that is between a perpendicular line drawn from the center of the first waveguide 129 toward the submount 101 and a joining end 137, located near the insulation trench 111, of a joined portion of the first semiconductor laser region 107 and the submount 101. A distance b is also defined as that between the perpendicular line and a joining end 139, placed toward a lateral side of the substrate, of the joined portion. Similarly, with respect to the side of the second semiconductor laser region 109, defined is a distance a′ that is between the perpendicular line drawn from the center of the second waveguide 159 toward the submount 101 and a joining end 167, located near the insulation trench 111, of a joined portion of the second semiconductor laser region 109 and the submount 101. A distance b′ is also defined as that between the perpendicular line and a joining end 169, placed toward a lateral side of the substrate, of the joined portion.

In this embodiment, SnAg is used as a material for a solder layer that joins the laser chip 103 and the submount 101, and Sample 1 through Sample 4 are made with their laser chip width W, the distances a and a′, and the distances b and b′ being varied. The thus implemented semiconductor laser devices are evaluated to confirm improvement in polarization angle relative to semiconductor laser devices made as Comparison Examples 1 and 2 in which AuSn is used as a material for the solder layer joining the laser chip to the submount.

Sample 1 is a semiconductor laser device with its laser chip width W 240 μm, the distances a and a′ 27 μm each, and the distances b and b′ 42 μm each, that is, b/a=1.56 and b′/a′=1.56. Sample 2 is a semiconductor laser device with its laser chip width W 225 μm, the distances a and a′ 32 μm each, the distance band b′ 34.5 μm each, that is, b/a=1.08 and b′/a′=1.08. Sample 3 is a semiconductor laser device with its laser chip width W 200 μm, the distances a and a′ 32 μm each, and the distances b and b′ 22 μm each, that is, b/a=0.69 and b′/a′=0.69. Sample 4 is a semiconductor laser device with its laser chip width W 180 μm, the distances a and a′ 32 μm each, and the distances b and b′ 12 μm each, that is, b/a=0.38 and b′/a′=0.38. In Samples 1 through 4, SnAg is used for a solder layer that joins its semiconductor laser chip to its submount. Furthermore, a laser device is made as Comparison Example 1, with a laser chip that has the laser chip width W of 240 μm, the distances a and a′ of 27 μm each, and the distances b and b′ of 42 μm each, that is b/a=1.56 and b′/a′=1.56, and that is joined to a submount by a solder layer made of AuSn. In addition, a laser device is made as Comparison Example 2, with a laser chip that has the laser width W of 200 μm, the distances a and a′ of 32 μm each, and the distances b and b′ 22 μm each, that is b/a=0.69 and b′/a′=0.69, and that is joined to a submount by a solder layer made of AuSn.

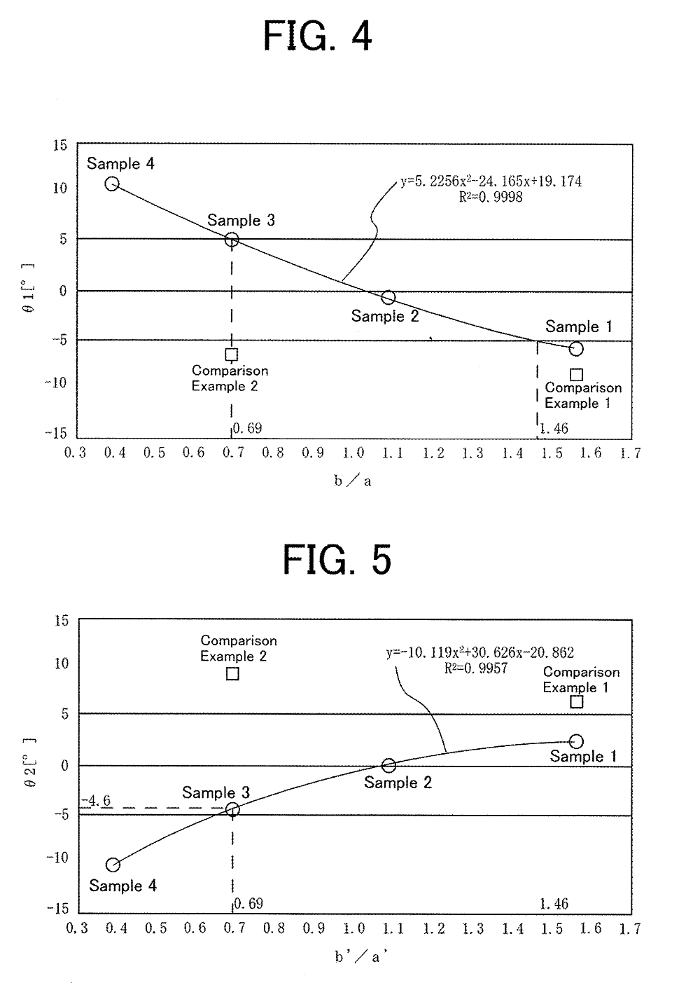

For the dual wavelength semiconductor laser devices as made above, measured are the polarization angle θ1 of the first semiconductor laser and the polarization angle θ2 of the second semiconductor laser. The polarization angle is determined by measuring variation in laser light intensity with a polarization prism being pivotally moved, and is the pivot angle of the polarization prism where the intensity takes its maximum value. It is better that the absolute value of the polarization angle be smaller. Tables 1 and 2 show measurement results of the polarization angles for Samples 1 through 4 and Comparison Examples 1 and 2 with their configurations. Using the results on Table 2, FIG. 4 is made by plotting the resultant data with the horizontal axis for (b/a) that is the divided value of distance b by distance a and with the vertical axis for polarization angle θ1 of the first semiconductor laser, and FIG. 5 is made by plotting the resultant data with the horizontal axis for (b′/a′) that is the divided value of distance b′ by distance a′ and with the vertical axis for polarization angle θ2 of the second semiconductor laser.

TABLE 1

| | solder | chip width (μm) | distance (m) | | | | | | | |
|---|---|---|---|---|---|---|---|---|---|---|
| | material | W | a | a′ | b | b′ | c | c′ | d | d′ |
| Sample 1 | SnAg | 240 | 27 | 27 | 42 | 42 | 55 | 55 | 65 | 57.5 |
| Sample 2 | SnAg | 225 | 32 | 32 | 34.5 | 34.5 | 55 | 55 | 57.5 | 57.5 |
| Sample 3 | SnAg | 200 | 32 | 32 | 22 | 22 | 55 | 55 | 45 | 45 |
| Sample 4 | SnAg | 180 | 32 | 32 | 12 | 12 | 55 | 55 | 35 | 35 |
| Comparison | AuSn | 240 | 27 | 27 | 42 | 42 | 55 | 55 | 65 | 65 |
| Example 1 | | | | | | | | | | |
| Comparison | AuSn | 200 | 32 | 32 | 22 | 22 | 55 | 55 | 45 | 45 |
| Example 2 | | | | | | | | | | |

TABLE 2

| | solder | chip width (μm) | division result | | | | polarization angle(°) | | (°) |
|---|---|---|---|---|---|---|---|---|---|
| | material | W | b/a | b′/a′ | d/c | d′/c′ | θ1 | θ2 | \|θ1 − θ2\| |
| Sample 1 | SnAg | 240 | 1.56 | 1.56 | 1.18 | 1.18 | −5.8 | 2.4 | 8.2 |
| Sample 2 | SnAg | 225 | 1.08 | 1.08 | 1.05 | 1.05 | −0.7 | 0 | 0.7 |
| Sample 3 | SnAg | 200 | 0.69 | 0.69 | 0.82 | 0.82 | 4.9 | −4.1 | 9 |
| Sample 4 | SnAg | 180 | 0.38 | 0.38 | 0.64 | 0.64 | 10.9 | −11 | 21.9 |
| Comparison | AuSn | 240 | 1.56 | 1.56 | 1.18 | 1.18 | −9.8 | 7.1 | 16.9 |
| Example 1 | | | | | | | | | |
| Comparison | AuSn | 200 | 0.69 | 0.69 | 0.82 | 0.82 | −6.7 | 8.9 | 15.6 |
| Example 2 | | | | | | | | | |

Firstly, in order to verify an effect due to the difference of solder materials, Sample 1 will be compared with Comparison Example 1. Table 1 shows that structures of these semiconductor laser devices only differ in solder material that joins the laser chip to submount. Sample 1 is significantly improved to have θ1=−5.8° and θ2=2.4° in comparison with Comparison Example 1 of θ1=−9.8° and θ2=7.1°. As described in Patent document 2, it is sometimes typical that in an optical pick-up where a dual wavelength semiconductor laser is used, design efforts are mainly made for a 650 nm-wavelength band laser. In this case, when an absolute value of the difference between polarization angles of a 780 nm-wave-length-band laser beam and a 650 nm-wavelength-band-laser beam is large, optical loss in the 780 nm-wavelength-band laser beam becomes large in the optical pick-up, and thus it becomes necessary for the 780 nm-wavelength band laser to be outputted with a higher light output. Thus, it is better that the absolute value |θ1-θ2| of the difference between the polarization angle θ1 of the first semiconductor laser and the polarization angle θ2 of the second semiconductor laser be smaller. When comparing values in |θ1-θ2|, there exists 16.9° in Comparison Example 1, but the value is halved to 8.2° in Sample 1, showing a great improvement.

The reason why measuring results described above are obtained is understood as follows. The solder layer of Comparison Example 1 is made, similarly to the case of a conventional dual wavelength semiconductor laser, of AuSn whose eutectic point is about 280° C., whereas the solder layer of Sample 1 is made of SnAg whose eutectic point is as low as 221° C. Because the semiconductor laser chip is installed on the submount under a high temperature, after its installation, the difference between the thermal expansion coefficients of the semiconductor and the submount produces built-in stress applied to the semiconductor laser chip. That is to say, the higher the melting temperature of solder to be used, the greater this built-in stress. Thus, it is understood that built-in stress that is nonuniformly applied in the chip-width direction (the X direction) to both waveguides 129 and 159 in the first semiconductor laser region 107 and the second semiconductor laser region 109 is reduced further in Sample than in Comparison Example 1, to thereby attain the polarization angle improvement as described above.

Especially in the case where a laser chip is mounted by junction down, an optical waveguide—a light emitting portion—is positioned closer to a portion joining to solder, to suffer a lot of the built-in stress described above. Moreover, in the case where a laser chip is provided with a ridge-type optical waveguide, a convex shape in its ridge structure makes its built-in stress concentrated at the ridge structure, thereby likely causing degradation in its polarization angle. Thus, the improvement in polarization angle represents a greater effect.

In Embodiment 1, because the SnAg solder is used to join the laser chip 103 to the submount 101, it is possible to significantly improve the polarization angle without using a submount that is required to have the optimized width and thickness and thus degrades the manufacturing efficiency. The SnAg solder also excels the SnPb solder, the SnBi solder and the like in a view point of fatigue life. Therefore, when the SnAg solder is used for joining a ridge-type-dual-wavelength laser in which built-in stress tends to be concentrated at ridge structures, it is possible to provide a laser having a high reliability and being improved in its polarization angle as well. In addition, the AuSn solder that is conventionally used contains 80 Wt % of expensive Au, whereas the SnAg solder contains 96 Wt % of inexpensive Sn, thus enabling cost reduction in manufacturing the semiconductor laser.

Next, in order to compare Samples 1 through 4 among each other, attention is made to (b/a) that is the divided value of distance b by distance a, and (b′/a′), that is the divided value of distance b′ by a distance a′. As is obvious from FIG. 4 and FIG. 5 where polarization angle measurements (θ1, θ2) shown in Table 1 are plotted, there is shown a tendency that the closer to one the values b/a and b′/a′ approach, the closer to 0° the angles θ1 and θ2 approach, respectively. It is also understood that the angles θ1 and θ2 tend to be in oppositional relationship regarding plus/minus signs. That is, there is a tendency that when θ1 is in plus-side, θ2 is in minus-side, and when θ1 is in minus-side, θ2 is in plus-side.

The results obtained above by comparing Samples 1 through 4 among each other can be interpreted below. Firstly, in the first semiconductor laser region 107, a structure where b/a is closer to 1 means that the joined portion between the first semiconductor laser region 107 and the solder layer 141 is closer to left-right symmetry with respect to the first waveguide 129 in the chip-width direction (the X direction). Therefore, it is considered that the value b/a closer to 1 reduces the degree of left-right unevenness inbuilt-in stress applied to the first waveguide 129, making a polarization angle closer to 0°. This holds true for the case of the second semiconductor laser region 109. In addition, typically, the first semiconductor laser region 107 and the second semiconductor laser region 109 are arranged in the different sides—right and left—with respect to the laser chip's center line, and thus it is considered that built-in stresses applied to the waveguides 129 and 159 are directed in different directions—rightward and leftward, causing different signs—positive and negative—in θ1 and θ2.

Here, considerations will be made on results of the polarization angles of Comparison Example 2. In Comparison Example 2, AuSn is used for the solder layer similarly to Comparison Example 1. As is understood from FIG. 4 and FIG. 5, in both Comparison Example 1 and 2, there is a completely different feature from that of Sample 1 through 4 in which SnAg is used for the solder layer, that is, θ1 and θ2 have little dependency on b/a and b′/a′, and θ1 is biased towards the negative (minus) side and θ2 is biased towards the positive (plus) side. In the monolithic dual wavelength semiconductor laser, because the first semiconductor laser region and the second semiconductor laser region are formed on a single substrate, the waveguide of the first semiconductor laser region suffers not only built-in stress produced by joining the first semiconductor laser region to the submount, but also built-in stress produced by joining the second semiconductor laser region to the submount. That is, in the case where AuSn solder is used which has a high melting temperature to cause a large built-in stress, it may be considered that such a built-in stress influences more dominantly than a built-in stress due to left-right asymmetry with respect to the first waveguide in width direction of the joined portion, bringing less θ1's dependency on b/a. On the other hand, in the case where SnAg solder is used, it may be considered that a built-in stress applied to the whole laser chip is reduced to make dominant a built-in stress due to left-right asymmetry with respect to the first waveguide in width direction of the joined portion, bringing high θ1's dependency on b/a. This holds true for the second waveguide.

In Embodiment 1, the laser chip width W was also varied together with the distances a, a′, b, and b′, and then how the chip width influences the polarization angle will be evaluated. Here, in order to similarly evaluate an influence by the width of the joined portions of the laser chip and the solder layers, the following are defined with respect to the chip-width direction of the laser-chip.

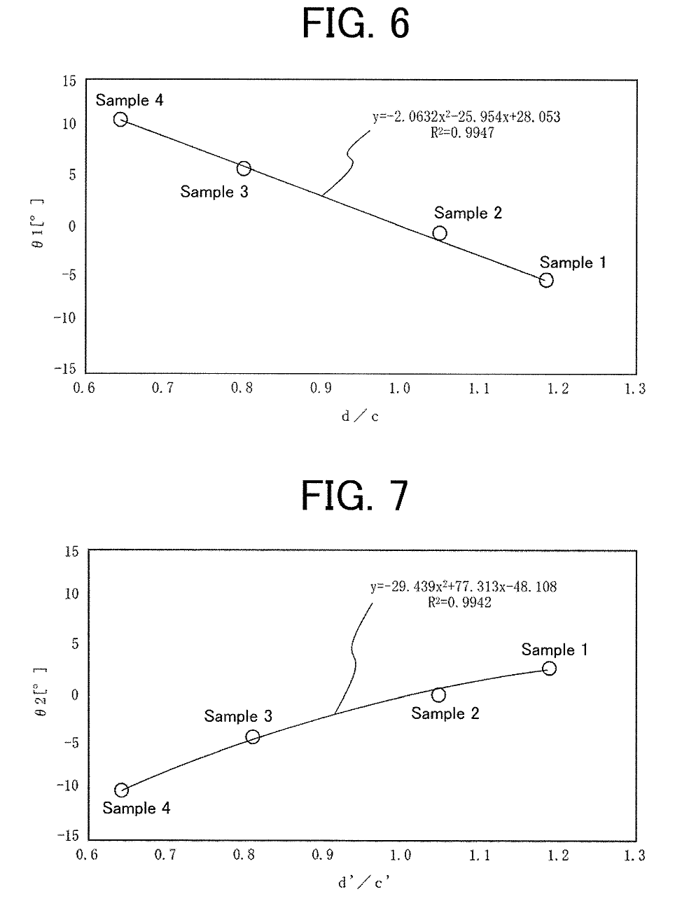

As shown in FIG. 1, with respect to the first semiconductor laser region 107, defined is a distance c that is between the perpendicular line drawn from the center of the first waveguide 129 toward the submount 101 and the center line of the n-GaAs substrate 105 that is centered in the chip width (in the x direction). A distance d is also defined as that between the perpendicular line and a side face 145 that constitutes a lateral side of the n-GaAs substrate 105 positioned on the first laser region 107. With respect to the second semiconductor laser region 109, defined is a distance c′ that is between the perpendicular line drawn from the center of the second waveguide 159 toward the submount 101 and the center line of the n-GaAs substrate 105. A distance d′ is also defined as that between the perpendicular line and a side face 175 that constitutes a lateral side of the n-GaAs substrate 105 positioned on the second laser region 109. Table 1 also shows distances c, c′, d, and d′, and divided values (d/c) and (d′/c′) of Samples 1 through 4. FIG. 6 is made by plotting the resultant data with the horizontal axis for (d/c) that is the divided value of distance d by distance c and with the vertical axis for polarization angle θ1 of the first semiconductor, and FIG. 7 is made by plotting the resultant data with the horizontal axis for (d′/c′) that is the divided value of distance d′ by distance c′ and with the vertical axis for polarization angle θ2 of the second semiconductor laser.

There is shown a tendency, similarly to the divided values (b/a) and (b′/a′), that the closer to one the values d/c and d′/c′approach, the closer to 0° the angles θ1 and θ2 approach, respectively. According to these results, it may be understood that the closer to the center of the first semiconductor laser region 107 the first waveguide 129 is, the closer to 0° the polarization angle θ1 approaches, and the closer to the center of the second semiconductor laser region 109 the second waveguide 159 is, the closer to 0° the polarization angle θ2 approaches. Then, investigations have been made about which influence is more dominant to the polarization angles in the waveguides 129 and 159, that is caused from left-right symmetry in width of the joined portion or caused from left-right symmetry in each chip width of the laser regions (the widths of semiconductor portions composing resonators).

As shown in FIG. 4 and FIG. 5, when the respective θ1s and θ2s of Samples 1 through 4 against b/a and b′/a′ are regressed to determine quadratic curves by a least-square method, obtained are equations (1) and (3) and coefficients of determination as shown in equations (2) and (4).

α=5.2256×(b/a)²−24.165×(b/a)+19.174 (1)

R(α)²=0.9998 (2)

α′=−10.119×(b′/a′)²+30.626×(b′/a′)−20.862 (3)

R(α′)²=0.9957 (4)

where

α and α′ are polarization angles [°] obtained from the quadratic regression curves of θ1 vs. b/a and θ2 vs. b′/a′, respectively, and

R(α)² and R(α′)² are coefficients of determination in equations (1) and (3), respectively.

On the other hand, as are shown in FIG. 6 and FIG. 7, when the respective θ1s and θ2s of Samples 1 through 4 against d/c and d′/c′ are regressed to determine quadratic curves by a least-square method, obtained are equations (5) and (7) and coefficients of determination as shown in equations (6) and (8).

β=−2.0632×(d/c)²−25.954×(d/c)+28.053 (5)

R(β)²=0.9947 (6)

β′=−29.439×(d′/c′)²+77.313×(d′/c′)−48.108 (7)

R(β′)²=0.9942 (8)

where

β and β′ are polarization angles [°] obtained from the quadratic regression curves of θ1 vs. d/c and θ2 vs. d′/c′, respectively, and

R(β)² and R(β′)² are coefficients of determination in equations (5) and (7), respectively.

As described above, in the first semiconductor laser, the determination coefficient R(α)² obtained by regressing θ1 against b/a to the curve is larger than the determination coefficient R(β)² obtained by regressing against d/c. This can be concluded that the regression curve obtained for b/a and θ1 better fits to the actual measurements. Similarly, in the second semiconductor laser, because the determination coefficient R(α′)² is larger than the determination coefficient R(β′)², it can be concluded that the regression curve obtained for b′/a′ and θ2 better fits to the actual measurements. From these investigation results, it is understood that left-right asymmetry in width of the joined portion influences the polarization angle strongly than left-right asymmetry in the chip width.

As is described in Patent document 2, it is typically considered that a semiconductor laser with its polarization angle within ±5° is good in polarization characteristic. In addition, if a dual wavelength semiconductor laser outputs two laser beams with different wavelengths both having polarization angle within ±5°, the semiconductor laser enables an easy design of optical pick-ups and allows using inexpensive materials. Therefore, it is understood from FIGS. 4 and 5 that by limiting b/a and b′/a′ within a range of 0.69 to 1.46, both the first semiconductor laser region and the second semiconductor laser region can have a good characteristic in that their polarization angles are within ±5° without using a submount disclosed in Patent document 1 that is required to have the optimized width and thickness and thus degrades the manufacturing efficiency, bringing advantages described above.

In addition, although SnAg is used for the solder layer in Embodiment 1, a solder material with its melting temperature lower than 221° C.—the SnAg's melting temperature at the eutectic point—may be used so far as each of b/a and b′/a′ is in the range from 0.69 to 1.46, to thereby suppress a built-in stress to be equal to or less than that produced in use of SnAg solder, which brings the same level of enhancement in polarization angle. Examples of such solder material include SnAgCu, SnAgBiCu, SnAgCuSb, SnZnBi, and the like.

Especially, SnAg solder has a long fatigue life, and therefore, when the SnAg solder is used to join a submount and a ridge-type-dual-wavelength laser to whose ridge structure built-in stress tends to be focused, a semiconductor laser device can be obtained with not just its polarization angle improved but a high reliability as well.

Furthermore, in Embodiment 1, it is better that each of a, a′, b, and b′ be 22 μm or more under the condition that b/a and b′/a′ are in a range between 0.69 and 1.46. This can prevent the laser chip from degradation in heat dissipation performance caused by an excessively narrow joined width between the laser chip and the solder.

Although in the semiconductor laser device according to Embodiment 1, the chip widths of the laser chip is in a range from 200 μm to 240 μm, the chip width of 220 μm or less is preferable in order to produce more semiconductor laser chips from a single semiconductor wafer. However, an excessively narrow chip width leads to a narrow width of the joined portion between the semiconductor laser chip and the solder to degrade its heat dissipation performance, and thus the chip width of 200 μm or more is preferable.

In addition, the semiconductor laser device according Embodiment 1 is formed to meet a requirement on designing an optical pick-up so that the distance between the first waveguide 129 and the second waveguide 159 is 110 μm, and therefore, the chip width of 220 μm brings left-right symmetry between the first semiconductor laser region 107 and the second semiconductor laser region 109, preferably allowing an easy work for designing electrode-width patterns and the like.

### Embodiment 2

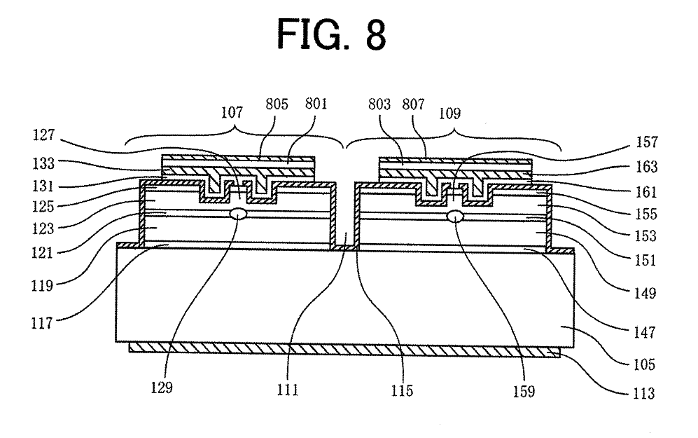

FIG. 8 is a cross-sectional view of a dual wavelength semiconductor laser chip used in a semiconductor laser device according to Embodiment 2. The dual wavelength semiconductor laser chip of the semiconductor laser device according to Embodiment 2 includes, on the p-side-electrode platings to be joined to a submount 101, barrier metal layers 801 and 803 made of Ni, Ta, Ti, Pt, Cr, or the like, and Au thin film layers 805 and 807 formed on the barrier metal layers with their thickness of 10 nm to 60 nm to prevent the barrier metals from getting oxidized. The Au thin film layers 805 and 807 may not be formed, if the barrier metal layers 801 and 803 can be prevented from getting oxidized by other methods. By forming the barrier metal layers on the dual wavelength semiconductor laser chip in a manner described above, it is possible to prevent development of depletions (voids) in the vicinity joining surfaces, which would otherwise be produced by mutual diffusion between the electrode material in the side of the laser chip and a solder material in the side of the submount. In addition, the barrier metal layer's thickness of 50 nm or more is preferable from the viewpoint of preventing the mutual diffusion, and that of 300 nm or less is preferable from the viewpoint of efficiently forming the barrier metal layers.

In addition, it should be understood that the embodiments disclosed in the specification is just examples and the present invention is not limited to the embodiments. The scope of the present invention is defined in Claim, and includes equivalence thereof and all modifications made within Claim.

### REFERENCE NUMERALS

101 submount
103 dual wavelength semiconductor laser chip
105 n-GaAs substrate
107 first semiconductor laser region
109 second semiconductor laser region
111 insulation trench
129, 159 waveguide
133, 163 electrode plating
135, 165 center line
137, 167 joining end of a joined portion that is located near the insulation trench
139, 169 another joining end of the joined portion that is placed toward a lateral side of the substrate
141, 171 solder layer
801, 803 barrier metal
805, 807 Au thin film layer

1. A semiconductor laser device comprising:
a dual wavelength semiconductor laser chip having a ridge-waveguide, including a substrate, a first laser region and a second laser region, on the substrate, and an insulating trench between the first laser region and the second laser region; and
a submount to which the dual wavelength semiconductor laser chip is joined, junction down, by a solder.

2. The semiconductor laser device according to claim 1, wherein the solder is an SnAg solder.

3. The semiconductor laser device according to claim 1, wherein the dual wavelength semiconductor laser chip has a width within a range from 200 μm to 220 μm.

4. The semiconductor laser device according to claim 1, wherein the dual wavelength semiconductor laser chip has an electrode layer on a contact portion contacting the solder, and the electrode layer includes a barrier metal layer selected from the group consisting of Ni, Ta, Ti, Pt, and Cr and that forms a connection surface of the electrode layers that is connected to the solder.

5. The semiconductor laser device according to claim 2, wherein the dual wavelength semiconductor laser chip has an electrode layer on a contact portion contacting the solder, and the electrode layer includes a barrier metal layer selected from the group consisting of Ni, Ta, Ti, Pt, and Cr and that forms a connection surface of the electrode layer that is connected to the solder.

6. The semiconductor laser device according to claim 5, wherein the barrier metal layer has a thickness within a range from 50 nm to 300 nm.

7. A semiconductor laser device comprising:
a dual wavelength semiconductor laser chip having a ridge-waveguide, and including a substrate, a first laser region including a first waveguide and a second laser region including a second waveguide, on the substrate, and an insulating trench between the first laser region and the second laser region; and
a submount to which the dual wavelength semiconductor laser chip is joined, junction down, by a solder having a melting temperature not exceeding 221° C., wherein
0.69≦b/a≦1.46, and 0.69≦b′/a′1.46
where
a is distance between a center line of the first waveguide and a first joining end of a joined portion of the first laser region and the submount and that is located toward the insulation trench,
b is distance between the center line of the first waveguide and a second joining end of the joined portion of the first laser region and the submount and that is located toward a lateral side of the substrates, near the first laser region,
a′ is distance between a center line of the second waveguide and a first joining end of a joined portion of the second laser region and the submount and that is located toward the insulation trench,
b′ is distance between the center line of the second waveguide and a second joining end of the joined portion of the second laser region and the submount and that is located toward a lateral side of the substrate located near the second laser region.

8. The semiconductor laser device according to claim 7, wherein the solder is an SnAg solder.

9. The semiconductor laser device according to claim 7, wherein each of a, a′, b, and b′ is at least 22 μm.

10. The semiconductor laser device according to claim 7, wherein the dual wavelength semiconductor laser chip has a width within a range from 200 μm to 220 μm.

11. The semiconductor laser device according to claim 10, wherein the dual wavelength semiconductor laser chip has a width of 220 μm.

12. The semiconductor laser device according to claim 7, wherein the dual wavelength semiconductor laser chip has an electrode layer on a contact portion for the solder, and the electrode layer includes a barrier metal layer selected from the group consisting of Ni, Ta, Ti, Pt, and Cr, and that forms a connection surface of the electrode layer that is connected with the solder.

13. The semiconductor laser device according to claim 12, wherein the barrier metal layer has a thickness within a range from 50 nm to 300 nm.

14. The semiconductor laser device according to claim 1, wherein the dual wavelength semiconductor laser chip has an electrode layer on a contact portion contacting the solder, and the electrode layer includes a barrier metal layer selected from the group consisting of Ni, Ta, Ti, Pt, and Cr, and that is spaced 10 nm to 60 nm from the connection surface of the electrode layer.

15. The semiconductor laser device according to claim 2, wherein the dual wavelength semiconductor laser chip has an electrode layer on a contact portion contacting the solder, and the electrode layer includes a barrier metal layer selecting from the group consisting of Ni, Ta, Ti, Pt, and Cr, and that is spaced 10 nm to 60 nm from the connection surface of the electrode layer.

16. The semiconductor laser device according to claim 15, wherein the barrier metal layer has a thickness within a range from 50 nm to 300 nm.

17. The semiconductor laser device according to claim 16, wherein the barrier metal layer has a thickness within a range from 50 nm to 300 nm.
